(19) United States
(12) Patent Application Publication
(10) Pub. No.: US 2010/0195675 A1
(43) Pub. Date: Aug. 5, 2010

(54) Terahertz and millimeter wave source

(76) Inventors: Jerome V. Moloney, Tucson, AZ (US); Mahmoud Faliahi, Tucson, AZ (US); Li Fan, Tucson, AZ (US); Stephan W. Koch, Fronhausen (DE); Martin Koch, Kirchhain (DE); Maik Scheller, Braunschweig (DE); Kai Banake, Cremlingen (DE)

Correspondence Address: DANN, DORFMAN, HERRELL & SKILLMAN, 1601 MARKET STREET, SUITE 2400, PHILADELPHIA, PA, 19103-2307, US

(21) Appl. No.: 12/397,139

(22) Filed: Mar. 3, 2009

Related U.S. Application Data
(60) Provisional application No. 61/067,949, filed on Mar. 3, 2008.

(30) Foreign Application Priority Data
Apr. 30, 2008 (DE) DE102008021791.3

(51) Int. Cl. H01S 3/30; H01S 5/183; H01S 5/026

(52) U.S. Cl. 372/4; 372/50.1

(57) ABSTRACT

The present invention relates generally to a terahertz and millimeter wave source, and more particularly, but not exclusively, to structures for coupling the terahertz electromagnetic waves out of the source.

### RELATED APPLICATIONS

This application claims the benefit of priority of U.S. Provisional Application No. 61/067,949, filed on Mar. 3, 2008, and claims the benefit of priority of German Patent Application DE102008021791.3, filed on Apr. 30, 2008, the entire contents of which applications are incorporated herein by reference.

### GOVERNMENT LICENSE RIGHTS

This invention was made with government support under, Grant Number F49620-02-1-0380 awarded by USAF/AFOSR. The government has certain rights in the invention.

### FIELD OF THE INVENTION

The present invention relates generally to a terahertz and millimeter wave source, and more particularly, but not exclusively, to structures for coupling the terahertz electromagnetic waves out of the source.

### BACKGROUND OF THE INVENTION

While almost all areas of the electromagnetic range are used technically, the so called terahertz range (THz), reaching from around 100 GHz to around 10 THz, has been relatively unexploited so far.

As THz waves possess a much smaller wavelength than classical microwaves, they are suitable for achieving spatial resolutions of less than one millimeter. This makes them interesting for many imaging applications in a whole variety of areas. This includes both security checks of persons, letters and luggage, as well as the control of completeness of packaged goods or the process control during the production of polymer composite materials. Furthermore, the “in-door” communication through THz waves promises to become a mass market from approx. 2015 onwards.

The terahertz frequency range is located between those of microwaves and infrared light. Thus, THz waves can be considered either as very high-frequency microwaves or as very long-wave light (far-infrared radiation). While all the other ranges of the electromagnetic spectrum are technologically used, the far-infrared spectrum of the terahertz frequencies forms a blank area on the electromagnetic map (see FIG. 1). The reason for this is the lack of efficient, cost-effective and compact THz emitters and receivers.

It is however not the case, that experiments with THz waves were impossible in the past. They were linked with a high experimental, i.e. financial effort and were summarized under the term far-infrared spectroscopy. By the middle of the last century, the THz properties of many materials were already investigated for the first time.

It is, however, also indisputable that significant progresses have been made in the field of THz components in the last years. As evidence for the increasing research activity in this field, FIG. 2 may be used, which shows the amount of publications found in the SPIN database to the keywords “THz” and “terahertz”.

### THz Sources in the State of the Art

Hereinafter, currently existing THz sources are briefly described. They are subdivided into pulsed and continuous wave sources. The performance which can typically be achieved with these sources and their current price are indicated respectively.

### Pulsed THz Sources:

### Photo-Conductive Dipole Antenna

A big step for THz technology was the appearance of mode-coupled titanium-sapphire lasers which emit pulses lasting only a few tens of femtoseconds. Since then numerous methods have been demonstrated which are suitable for generating and detecting THz pulses based on a femtosecond laser. The oldest and probably most widespread method is based on photoconductive antennas which are excited by femtosecond pulses. These antennas consist of a piece of gallium arsenide onto which two parallel metal stripe conductors have been vapor deposited. The laser pulses generate charge carriers between the conductors which are accelerated through an applied electrical field. The consequence is a short current pulse which represents the source of a THz pulse emitted into the space.

If an unamplified titanium-sapphire laser is used for the excitation, the CW power lies in the range of microwatts. The price level is prevailingly determined by the femtosecond laser and currently lies at 50,000 [symbol] .

Synchrotron, Free-Electron Lasers and Smith-PURCELL emitter

A less compact class of THz emitters, based on an electron beam, comprises synchrotron, free-electron lasers, so called Smith-Purcell emitters and backward-wave tubes. In a synchrotron and in a free-electron laser, electrons are sent through a region with alternating magnetic fields in which they oscillate from one side to the other. This oscillating electron movement leads to the emission of THz radiation. The Smith-Purcell emitter is based on an electron microscope whose electron beam propagates along the surface of a metallic lattice. This very expensive class of sources has to be discarded for practical applications due to its considerable size.

### Backward-Wave Tube

Backward-wave tubes, also called carcinotrons, are approximately the size of a football. In these electrovacuum devices, electrons fly over a comb-like structure, which combines them in periodic bundles, leading to the emission of THz radiation. Although they are not modern devices, backward-wave tubes are high-power sources, which are able to generate 10 mW of monochromatic, but tunable THz power at several 100 GHz. The emitted performance declines with the frequency and the tuning range of a carcinogen amounts to approximately 100 GHz. At present, they are only produced in Russia and cost approx. 25,000 [symbol] and more.

### P-Germanium Laser

P-germanium lasers use transitions of holes from the light to the heavy hole band and deliver strong THz pulses: Until now, the p-germanium laser only worked, however, at low temperatures and in pulsed operation. Furthermore, it requires a magnetic field. This makes it unsuitable for applications outside of the laboratory. The costs lie in the range of 200,000 [symbol] .

### Quantum Cascade Laser

The quantum cascade laser (QCL) is a very promising technology for the realization of compact sources working at room temperature, monolithically, run with current, for the range from 1-5 THz. QCL were presented for the first time in 1994 by Faist and colleagues. Early QCL still required cryogenic cooling, worked only in pulsed operation, and emitted in the middle infrared range. Considerable progress has been made since the first beginnings Development went to continuous wave, higher temperatures and bigger wavelengths. Nowadays, QCL, which are run in the middle infrared range, run in cw mode and at temperatures, which exceed even room temperature. These QCL are suitable for industrial applications.

Until the late nineties, it was assumed that the working frequency could never been brought under 5 THz. In 2002, however, Tredicucci and colleagues presented a QCL which worked at 4.4 THz. In 2004, a QCL was presented, which emitted continuous radiation at 3.2 THz up to a temperature of 93 K. The cw output power at 10K amounted hereby to 1.8 mW. The output power in pulsed operation of THz QCLs is always higher, namely in the range of many mW. Furthermore, pulsed THz QCLs work at higher temperatures, but still require cooling.

In 2006, another group demonstrated a QCL for a frequency of 2 THz, which allowed for a cw mode at 47 K and had a maximum power of 15 mW at T=4K. In the year 2007, a third group achieved a cw power of 24 mW at 20K and a frequency of 2.8 THz. As a result of this, light, portable THz sources are able to be produced with the help of Stirling coolers with closed cycle. THz QCLs based sources cost between 50,000 and 100,000 .

### Continuous Wave THz Sources:

### THz Gas Laser

Molecular gas lasers, also referred to as FIR lasers, are based on transitions between different rotational states of a molecular species. Hereby, they are suitable for emitting an output in the tens of mW range at discrete THz frequencies. The discrete operating frequencies range from less than 300 GHz to more than 10 THz. The most intensive methanol line is obtained at 2.52 THz. Such a laser has to be pumped, however, by a tunable carbon dioxide laser. This implies a big space requirement for the entire system. Unfortunately, THz gas lasers are not only bulky, but also expensive (almost 100,000 [symbol] ).

### Quantum Cascade Laser

Quantum cascade lasers have already been discussed above as a pulsed THz source. They also run in cw mode, but with lower power, which has also been discussed above.

### Emitters Based on Classical Microwave Technique

THz emitters are suitable for being realized with the help of microwave technology based on Gunn, Impatt or resonant tunnel diodes. As the fundamental frequencies of these systems are in most cases not high enough for many THz applications, they have to be multiplied first by specific mixers. A THz source based on microwave technology fits easily in a shoe box. Typically, they cost several tens of thousands of euros. The power at frequencies above one THz is under 1 mW and the sources are only partly tunable. The tunability lies in the range of few tens of GHz.

### Photomixer

A widely spread method for the generation of THz radiation is based on photoconductive THz antennas which are excited optically by two cw laser diodes oscillating with slightly different frequency. The emission of these lasers is superposed on the antenna, which is also referred to as Photomixer when excited with cw lasers. The resulting beat of light is hereby converted into an oscillating antenna current which is the source of a monochromatic THz wave. The achieved power lies at a few μW. Including the pump lasers, a THz source costs 10,000 to 20,000.

### Direct Radiation of Two-Color Lasers

Recently, Hoffmann and colleagues (University of Bochum) were able to show that two-color lasers emit even THz radiation due to a nonlinear process. However, the radiation power was very low and was located at the detection limit. The price lies at a few 1,000 [symbol] .

The following table summarizes the data of the available cw THz systems, and includes for comparison data for an exemplary device of the present invention in the last row. Amongst others, the power P_max in the area of 1 THz, the tunability, the system size and costs are listed.

TABLE 1

| | | P_max | | System | Price (in | |
|---|---|---|---|---|---|---|
| Method | CW | (mW) | Tunability | size | thousand $) | Remarks |
| Gas laser | X | up to 50 | discrete | big | 100 | strongest line at 2.5 |
| | | | lines | | | THz (50 mW), other |
| | | | | | | lines only emit few mW |
| Microwave | X | <1 | Hardly | shoe box | 60 | Power decreases above |
| Based | | | | | | 1 THz |
| Photomixing | X | 0.005 | Yes | small | 15 | Power decreases above |
| | | | | | | 1 THz |
| THz QCL | X | 30 | hardly | small | 50 | Requires cooling, |
| | | | | | | power improves yearly |
| New source | X | >>10 | yes | small | 50 | The power increases |
| of present | | | | | | with the frequency |
| invention | | | | | | |

In summary, it has to be noted that many different THz sources exist, each with its own advantages and defects.

The disadvantages often consist in the fact that the systems are very complex and, thus, expensive or/and relatively under-performing (power in the range of only μW) or/and are not tunable or/and are only suitable to be run in pulsed operation or even have to be cooled in a complex manner.

### SUMMARY OF THE INVENTION

A central idea of present the invention relates to generating terahertz (THz-) waves or millimeter waves by means of a non-linear medium positioned within the laser resonator of a Vertical Cavity Surface Emitting Laser (VECSEL) or of another laser (wherein the other laser is preferably a disc laser, for example) through difference-frequency generation. This THz-radiation is guided and extracted by means of THz optics which has been optimized for that purpose. The laser medium and the laser design are conceived in such a way that the highest possible THz generation and extraction are possible. Hereby, the optimal VECSEL laser medium is determined by a high amplification performance (a high gain), high spectral bandwidth and suitable spectral position in such a way that pump lasers, which are as economic and/or as powerful as possible, or other pump sources are suitable for being used.

A demonstrator has already been designed and THz performances in the area of several milliwatts have been attained in continuous-wave operation at room temperature. The corresponding device according to the present invention and the method are, however, also suitable for being used in pulsed mode operation. The presented practical embodiments allow expectations of THz performances of up to the watt range.

In one of its aspects, it is thus the aim of the invention to provide a device, including the novel singular components required therefore, as well as a method for the generation of terahertz or millimeter waves, which avoid(s) the aforementioned disadvantages as much as possible.

These aims are achieved concerning the device by the matter according to claims 6 to 10 and concerning the method by the matter according to claims 1 to 5 as well as concerning the novel singular components by the matter according to claim 11.

Surprisingly it has been found that different nonlinear media are suitable for being used in an intracavity manner in order to generate terahertz and millimeter waves, as they do not only resist the impinging power densities, but also ensure an efficient generation of frequency difference. This applies for continuous wave mode as well as for pulsed mode and also for spectral tunability of the entire device.

A summary of the power data of existing THz sources (FIG. 3) shows clearly the so called THz gap. In the range between few hundreds of GHz and several THz, no compact tunable sources exist at present. Our powerful “new THz source” which is described in the following is suitable for filling this gap. The power data indicated for the new source represent a conservative estimation. With some of the practical embodiments stated in the following, it is expected that the achievable THz power or/and the power in the range of millimeter waves are considerably higher.

### BRIEF DESCRIPTION OF THE DRAWINGS

The foregoing summary and the following detailed description of the preferred embodiments of the present invention will be best understood when read in conjunction with the appended drawings, in which:

FIG. 1 illustrates the electromagnetic spectrum;

FIG. 2 illustrates the increase in terahertz-related publications from 1986 to today;

FIG. 3 illustrates power data of existing THz sources along with power data expected from devices according to the present invention (“new source”), which promises a power improvement of several orders of magnitude as compared to systems which are already available;

FIG. 4 schematically illustrates an example of a waveguide in which different materials were used;

FIG. 5 schematically illustrates the polarity structure of a surface-emitting PPLN;

FIG. 6A schematically illustrates the periodic polarity of a TPPLN which is tilted at an angle of a;

FIG. 6B schematically illustrates the periodic polarity of chessboard crystal type with 2D polarity;

FIGS. 7A and 7B illustrate VECSEL spectrum in two color and many color operation, where the wavelength, as well as the frequency distance of the line, is able to be modified through tilting the etalon;

FIG. 7C schematically illustrates a current exemplary design of a device in accordance with the present invention for intracavity THz generation with a nonlinear crystal;

FIGS. 8A-E illustrate emitted THz output power of the TPPLN and the number of the oscillating laser lines at different output powers;

FIG. 9 illustrates THz output power emitted from the TPPLN bundled with an improved THz optics and detected with a Golay cell;

FIG. 10 illustrates THz output power at f=675 GHz and optimized resonator configuration;

FIG. 11A illustrates different semiconductor materials and wavelengths;

FIG. 11B illustrates lattice constants and band gap energies of several semiconductors;

FIG. 12 schematically illustrates an exemplary design of a device in accordance with the present invention having a two-color VECSEL with optical elements in the resonator;

FIG. 13 schematically illustrates an exemplary design of a device in accordance with the present invention having laser radiation of the VECSEL overlapped by one of an external laser in a nonlinear material found in the VECSEL resonator;

FIG. 14 schematically illustrates an exemplary design of a device in accordance with the present invention having two VECSELS in a joint resonator;

FIG. 15 schematically illustrates an exemplary design of a device in accordance with the present invention having two VECSELs with separated resonators, with the nonlinear material found at the intersection of both laser resonators;

FIG. 16A schematically illustrates an exemplary design of a device in accordance with the present invention having the laser radiation of two VECSELS overlapped outside the cavity and directed over one or several nonlinear materials which are found in a further external resonator;

FIG. 16B schematically illustrates an exemplary expanded, current design of a device in accordance with the present invention having design for intracavity THz generation with a nonlinear crystal and additional highly reflective (R>99%), concave mirror, which reflects the decoupled power back exactly in the resonator;

FIGS. 17A-D schematically illustrate different possibilities of separating the THz radiation from the optical radiation, where FIG. 17A schematically illustrates collinear THz generation with an external filter, FIG. 17B schematically illustrates collinear THz generation with a resonator-internal THz mirror, FIG. 17C schematically illustrates a collinear THz generation with a resonator-internal mirror for the optical wave, and FIG. 17D schematically illustrates an alternative where a surface-emitting crystal is suitable for serving as the source of the THz radiation;

FIG. 18A schematically illustrates total reflection which can occur at the boundary layer between the crystal and the air;

FIG. 18B schematically illustrates a outcoupling structure is suitable for avoiding total reflection;

FIGS. 19A-F schematically illustrate examples of quasi phase matching (QPM) possibilities in non-linear crystals, where FIG. 19A illustrates simple periodic polarity, FIG. 19B illustrates tilted periodic polarity, FIG. 19C illustrates chessboard-shaped polarity, FIG. 19D illustrates simple aperiodic polarity, FIG. 19E illustrates tilted aperiodic polarity, and FIG. 19F illustrates fan-out polarity.

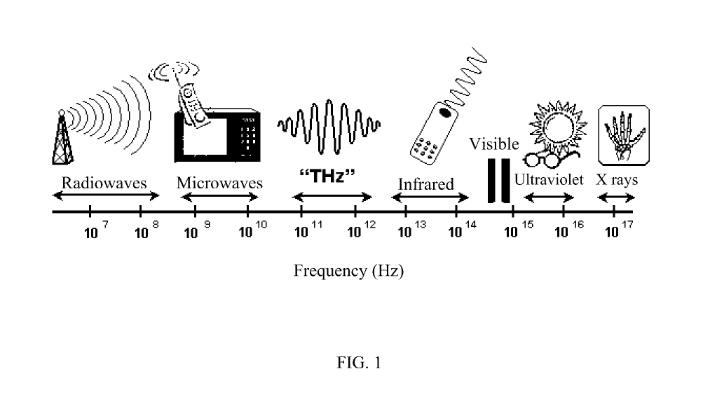

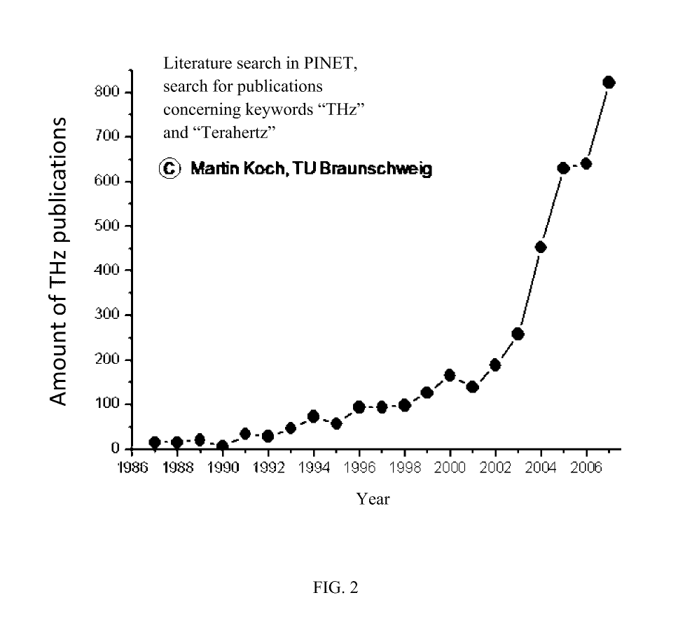

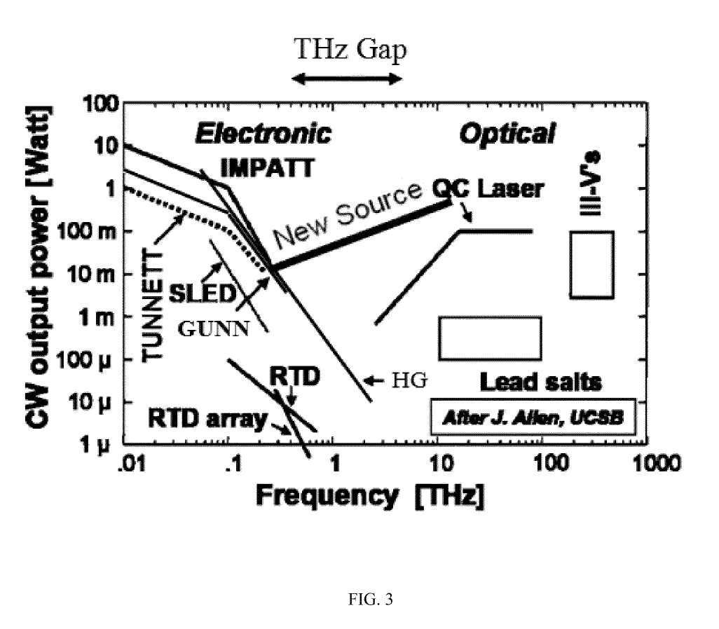

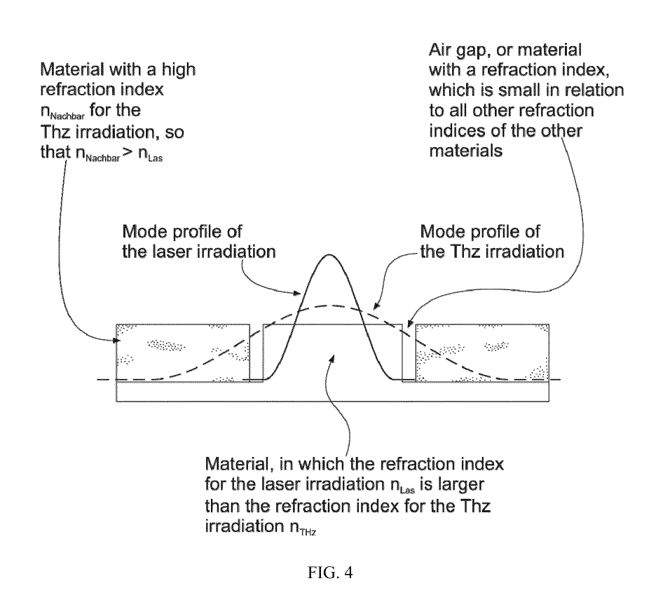

### DETAILED DESCRIPTION OF THE INVENTION

Based on the concept according to the present invention, first demonstration experiments have already been carried out by us, apart from detailed theoretical calculations and estimations, which firmly prove the far reaching potential of the presented invention. After only two simple optimization steps, we were able to achieve THz output powers in continuous wave operation at room temperature, which significantly exceed those of most of the sources known so far. At the moment, only THz gas lasers and THz quantum cascade lasers are slightly more powerful. These two source types are, in contrast to the source according to the present invention, not (or only to a very limited extent) spectrally tunable. In addition, even significantly higher THz powers with our source are expected after some further optimization steps.

Exemplary Components of the Devices According to the Present INVENTION (in some Practical Embodiments)

### Vertical External Cavity Surface Emitting Laser (VECSEL)

A VECSEL comprises a semiconductor structure composed of two different sequence layers. The first area of the structure is comprised of a sequence layer of quantum films, which are responsible for the laser activity, followed by an underlying Bragg mirror. Thus, the VECSEL chip itself provides one mirror of the laser resonator, whilst all further mirrors are located outside the semiconductor material. By means of a pump laser, the semiconductor material is optically excited. Alternatively, the excitation may also be achieved electrically. Through a suitable resonator configuration, a laser emission is achieved.

Through the use of frequency filtering elements inside the resonator, it is possible to limit the emission spectrum of the laser to certain frequencies within its gain spectrum. Such an element is, for example, an etalon which enables the limitation, upon suitable choice, of the emission spectrum to one or various frequencies. With two- or multi-color emission, it is possible to generate new emission wavelengths by means of nonlinear optical elements for frequency conversion (SHG, THG, difference frequency generation (DFG)).

### Nonlinear Crystals for Frequency Conversion

Nonlinear crystals are suitable for frequency conversion according to the present invention, i.e., for frequency multiplication or up-conversion, as well as for difference-frequency generation. For that, their high χ⁽²⁾ factor, which is denominated second order electrical susceptibility, can be decisive. Thereby, it is possible to carry out a frequency conversion of the irradiated laser light, provided that the laser intensity is sufficiently high in order to generate a measurable, converted output signal. The most different material compositions are eligible as nonlinear material, wherein, for each application, it has to be accurately checked beforehand which of the available materials is most suitable. Hereby, attention has to be paid to the respective absorption of the individual frequencies inside the crystal, as well to the phase matching between the generating and generated electromagnetic radiations. The latter represents a non-trivial challenge, as insufficient phase matching leads to a strongly reduced output signal, because the generated frequency components are attenuated again or completely extinguished by destructive interference. In order to ensure phase matching, three techniques have been examined. Ultimately, concerning the invention it has been shown that: firstly, an adjustment is able to be achieved by birefringence of the crystal; secondly by quasi phase matching (QPM) and thirdly by a waveguide configuration.

### Matching Via Birefringence

Many nonlinear crystals feature birefringent characteristics, i.e. the refraction index depends on the polarization direction of the electromagnetic wave relative to the crystal axis. Hereby, ordinary and extraordinary beams are differentiated. If a birefringent crystal is cut at a certain angle, then the effective refraction index of the extraordinary beam is able to be modified as a function of the cutting angle. Phase matching is achievable through this principle.

### Quasi Phase Matching

QPM is also able to be—for the realization of the invention—achieved, where ferroelectric domains are oriented opposing one another alternately in a crystal in the distance which corresponds to the half wavelength of the incoming laser light in the material. A weakening of the generated frequency through destructive interference is avoided, and the generated intensity of the electromagnetic irradiation increases with the path length in the crystal through the periodic pole reversal of the domains. Periodically poled lithium niobate (PPLN), along with many other materials, is a known representative. PPLN was used in the first demonstration of the technology applied for here in the patent and is described further below.

### Waveguide Geometry

Phase matching according to the present invention is also suitable for being achieved in that the nonlinear material is structured in order to realize a waveguide geometry. The aim of such a structuring is to achieve an identical effective refraction index of the nonlinear material for the laser wavelength and of the nonlinear material for the THz irradiation in the waveguide region, or refraction indices which only vary from one another as little as possible. In order to realize this, all waveguide configurations described in textbooks are available (see e.g. Karl J. Ebeling, Integrierte Optoelektronik, Springer, Berlin, 1992). Examples of this are raised strip waveguides, flushly embedded strip waveguides, buried strip waveguides, ridge waveguides, inverted ridge waveguides, dielectric slab waveguides, metal slab waveguides. However, countless further possibilities still result, since the nonlinear material (or the nonlinear materials) is (are) able to be combined with other materials as well, which comprise a very small or negligible nonlinear coefficient, but a refraction index suitable for achieving phase matching, for the realization of a waveguide.

Additionally, waveguides and/or nonlinear materials, which comprise photonic crystal structures or depend on so-called metamaterials with a negative refraction index, are also possible.

A high intensity of the laser irradiation in the crystal is necessary for a large conversion efficiency. Unfortunately, all materials possess a damage threshold. This effect is called “photorefractive effect” or “optical damage” with lithium niobate and is described in A. Ashkin, et al., “Optically-induced refractive index inhomogeneities in LiNbO₃ and LiTaO₃”, Appl. Phys. Lett., vol. 9, 1966. Due to the high laser intensity within the crystal, an alteration appears in the local refraction index and absorption ratio, which bends the laser beam and, consequently, ends the laser activity. However, this effect is reversible and is able to be reduced through intense heating of the crystal to temperatures around 170° C. or higher. In this, however, the effort of temperature stabilization increases considerably. On the other side, the intensity of the optical damage is able to be reduced through the doping of the LN with MgO. Thus, it can be advantageous to use MgO-doped LN (the material which is also used in the demonstrator of the present invention) as the crystal material for an improved efficiency.

While LN is promising for application in difference frequency generation (DFG) due to its large nonlinear coefficient, its high absorption of THz waves simultaneously prevents an application in a collinear assembly. In order to counteract this problem, a surface-emitting, intracavity THz-DFG concept was also used according to the present invention. Surface emission of coherent THz irradiation, which was generated through a DFG process, is able to be generated with a PPLN crystal.

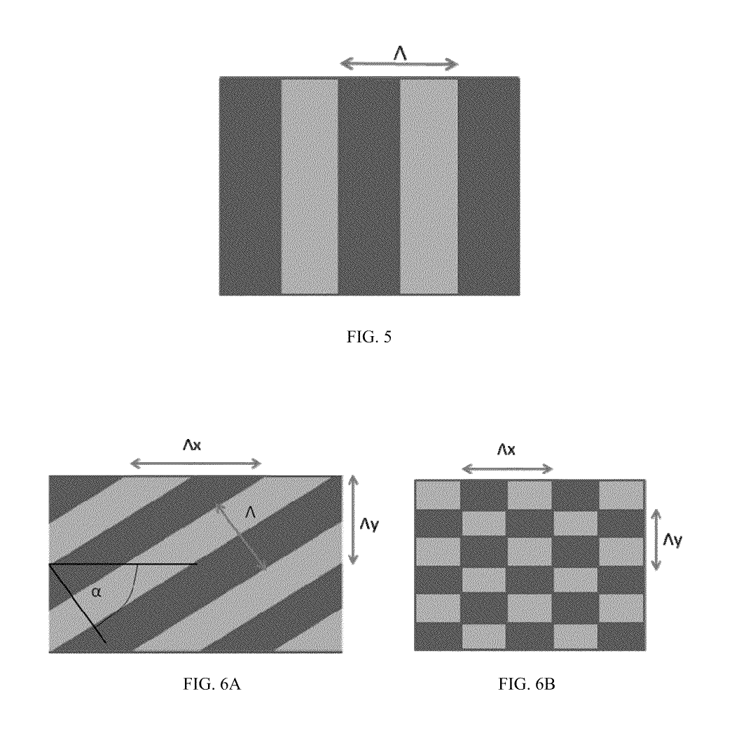

A simplest design of a PPLN is shown in FIG. 5. For an efficient surface emission, the polarity period A should be chosen as follows:

$$Λ = \frac{{λ}_{THz}}{{n}_{IR}}$$

Wherein n_{IR} is the refraction index of the IR wave and λ_{THz} is the free-space wavelength.

In order to avoid destructive interference of the generated THz radiation, with use of this simplified design, and in order to obtain a high THz output power, it is necessary to use a very low diameter of the laser irradiation within the PPLN. However, the useful crystal length is limited through the divergence of the laser ray. Hereby, it has to be mentioned that the smaller the ray diameter chosen, the larger the resulting ray divergence is.

While the simple PPLN design shown in FIG. 5 suffices for VECSEL systems with low IR power, the DFG THz demonstrator introduced here for the first time is based on an expanded crystal design. A tilted periodically poled lithium niobate (TPPLN) crystal was used, in order to no longer be limited through an IR ray diameter which is too small. This structure is tilted in reference to the crystal surface. Thus, periodic polarity also occurs in the direction of the radiated THz wave. Subsequently, the destructive interference of the THz wave is compensated through this and the IR ray diameter is able to be chosen considerably larger without reducing the conversion efficiency. In FIG. 6A, a TPPLN structure is shown. Here it is noteworthy, that even with a chessboard example, as is shown in FIG. 6B, a periodic 2D polarity, whose behavior is comparable with the TPPLN structure, is able to be realized. Both are suitable for being used according to the present invention.

For high conversion efficiency, the parameters should be determined as follows:

$$tan ( α ) = \frac{{n}_{THz}}{{n}_{IR}} , \\ Λ = \frac{{λ}_{THz}}{{n}_{IR}} cos ( α ) , \\ {Λ}_{x} = \frac{{λ}_{THz}}{{n}_{IR}} , \\ {Λ}_{y} = \frac{{λ}_{THz}}{{n}_{THz}} .$$

Wherein n_{1R} is the refraction index of the IR radiation, n_{THz} is the THz refraction index and λ_{THz} is the free-space wavelength of the THz irradiation. Furthermore, a is the tilting angle and Λ is the polarity period.

In the past few years, it has been shown that electro-optical polymers comprise a nonlinear χ(2)-coefficient, which is sufficient for generating THz waves by means of difference frequency generation (or optical rectification) (see, for example, L. Michael Hayden, et al., “New materials for optical rectification and electro-optic sampling of ultra-short pulses in the THz regime”, J. Polymer Sci. B. Polymer Phys, vol. 41, pp. 2492-2500, 2003; A. M. Sinyukov, et al., “Efficient electro-optic polymers for THz applications”, J. Phys. Chem. B, vol. 108, pp. 8515-8522, 2004; Xuemei Zheng, et al., “Broadband and gap-free response of a terahertz system based on a poled polymer emitter-sensor pair”, Applied Physics Letters, vol. 87, no. 8, pp. 081115, 2005).

Thus, a further class of materials is opened, which is suitable for being applied as a nonlinear medium according to the present invention.

Silicon is also suitable for being used as a nonlinear medium. Normally, silicon does not comprise a nonlinear χ⁽²⁾-coefficient. In Rune S. Jacobsen, et al., “Strained silicon as a new electro-optic material”, Nature, vol. 441, pp. 199-202, 2006, it is shown that a significant nonlinear coefficient is able to be achieved in silicon through a strain-induced symmetry breaking Strained silicon is suitable for being subsequently applied as a nonlinear material for generating THz radiation.

Frequency Conversion within a Cavity (preferably) SHG

The arrangement of the nonlinear element within the resonator lends itself to frequency conversion, since the optical intensity here is significantly higher than with the use of the outcoupled laser beam. Thereby, the conversion efficiency increases by a considerable amount because the nonconverted laser power does not become lost, but rather is reflected through the resonator mirror back through the crystal. Thus, even low conversion efficiency is sufficient to achieve high resulting frequency conversion efficiency with a simple cycle through the crystal. The only difference to a laser without a nonlinear element in the resonator is that a resonator mirror has to be replaced by one with dichromatic properties, in order to couple the waves generated through frequency conversion out of the resonator.

### Design of the Demonstrators

It is mentioned here that the experimental design introduced here actually represents an example of an embodiment and other embodiments or working examples that are likewise able to be realized.

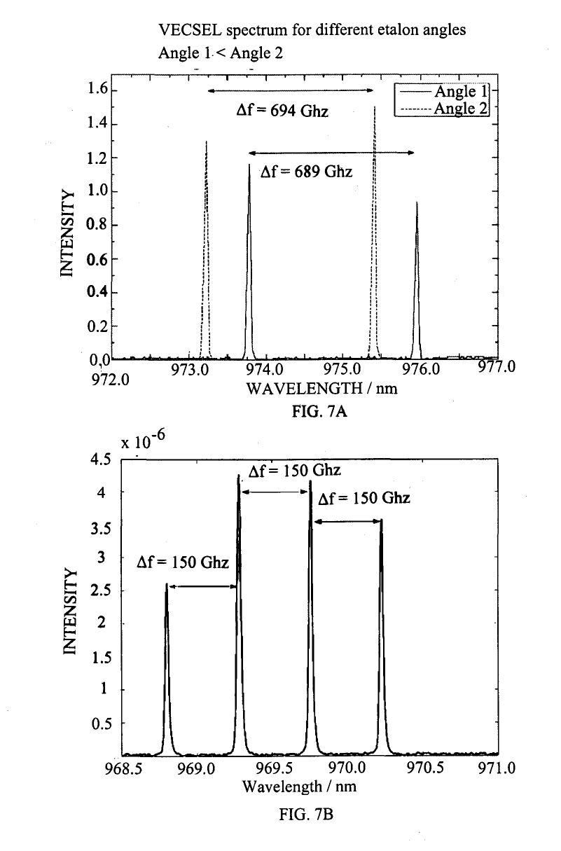

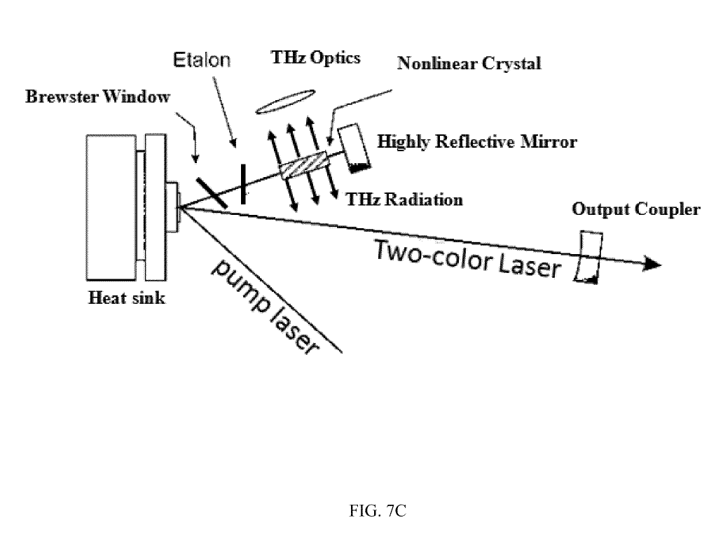

The schematic drawing in FIG. 7C shows the design of the two color VECSELs used in our demonstrator, which is already realized. These VECSELs comprise a nonlinear crystal and THz optics. The nonlinear material is comprised of lithium niobate (LN) with tilted, periodic polarity (TPPLN).

The laser design used comprises a V-shaped resonator, which is limited by two mirrors, a convex output coupler with a reflectivity of 97% and a highly reflective, planar mirror with a reflectivity of over 99%. The active laser medium is located on top of a heat sink at the folding point of the resonator and is pumped by a pump laser which is emitted at a wavelength of 810 nm.

Further elements used include an etalon for generating two or more wavelengths, as shown by both of the spectra in FIGS. 7A, 7B. It is also possible to shift the difference frequency in certain boundaries through tilting of the etalon. A Brewster window was also used for the adjustment of the polarization of the laser radiation and THz optics were also used for the bundling and focusing of the emitted THz waves on a detector. The THz radiation was able to be detected with a bolometer, a Golay cell and a pyroelectric detector. (The detector and the second THz lens are not represented in FIG. 7C.)

The placement of the nonlinear crystal was realized near the highly reflective mirror because here the laser beam achieves its lowest diameter within the resonator.

With the tilted orientation, according to the present invention, of the polarity of the nonlinear crystal used, the outcoupling of the THz radiation out of the crystal is able to occur advantageously in the right angle of the propagation direction of the laser beam. Most of the nonlinear crystals are transparent for the laser radiation but more or less absorb the THz waves. Outcoupling of the THz radiation out of the side surface of the crystal reduces the distance which the THz wave has to cover and, consequently, also the absorption within the crystal. Furthermore, a lateral outcoupling of the electromagnetic THz wave out of the crystal also means considerably easier access to the radiation, as well considerably simpler positioning of the THz optics, since there are no optics of the laser resonator in this region.

In order to ensure efficient generation of the THz radiation, phase matching has to be present between the laser radiation and the THz wave. According to the present invention, this was achieved through use of periodically poled materials. Thus, in this design, periodically poled lithium niobate, which was doped with MgO, was used, in order to raise the damage threshold.

### First Experimental Results

In this section, the experimental results which have been achieved with the demonstrator are presented.

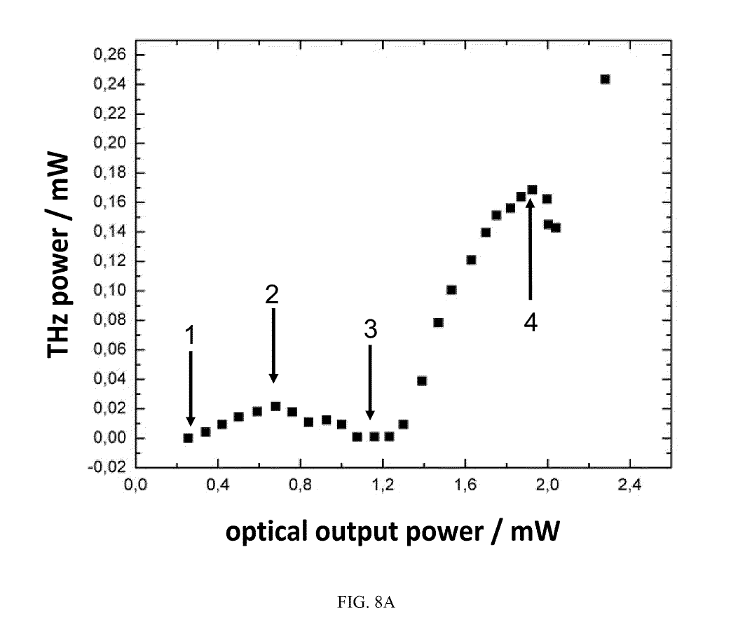

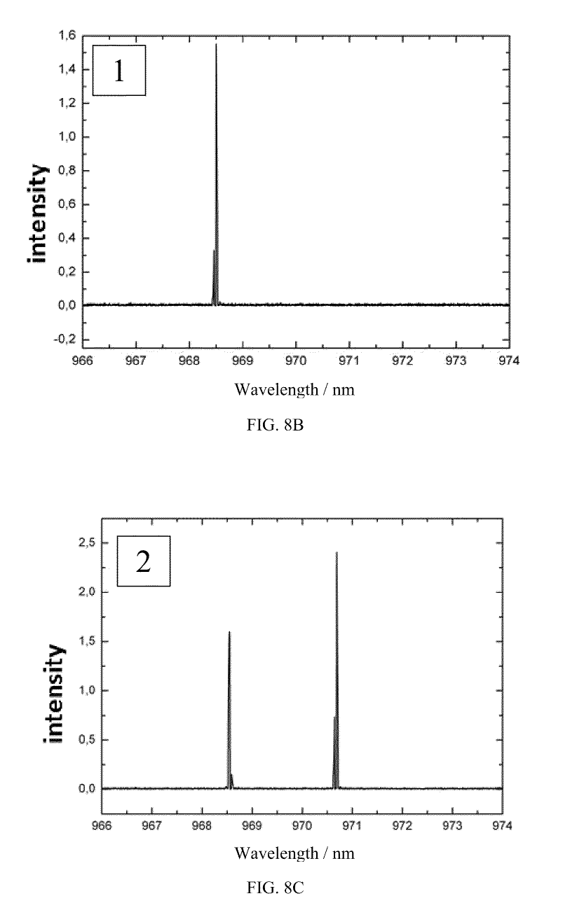

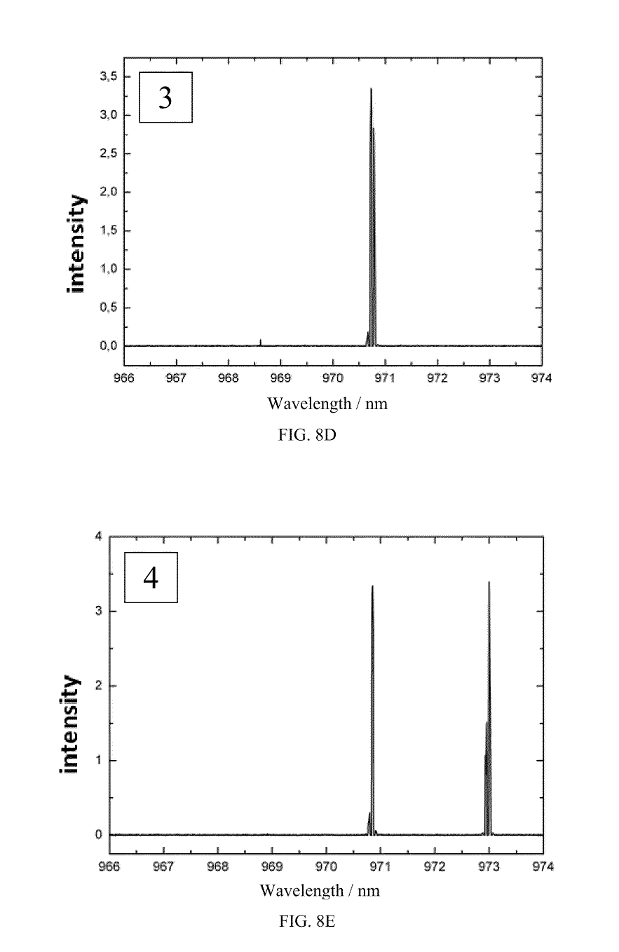

In FIG. 8A, the first outcome of measuring the THz radiation generated is shown as a function of the optical power which is coupled out of the laser cavity. A bolometer, with which a maximal THz output power of 0.24 mW was able to be measured, was applied as a THz detector. Additionally, four spectra for different output powers, which were recorded by an optical spectral analyzer, are presented, FIGS. 8B-8E.

These spectra prove that the measured detector signal only comes from the THz radiation, which was generated by means of difference frequency generation (DFG) in the TPPLN. It can clearly be seen that the bolometer signal only takes on values different from zero when both laser lines are simultaneously present (spectra #2, FIG. 8C, and #4, FIG. 8E). With the output powers in which the spectra #1, FIG. 8B, and #3, FIG. 8D, were recorded, only one laser line oscillated and, thus, no DFG process takes place and no THz wave is generated. The signal disappears and simply existing noise is measurable.

With increased optical output power and, thus, increased power within the laser cavity, a thermally induced red-shift of the laser lines is observable. This shift has no effect on the DFG process, since the difference frequency remains constant. This depends only on the intracavity etalon and not on the laser power.

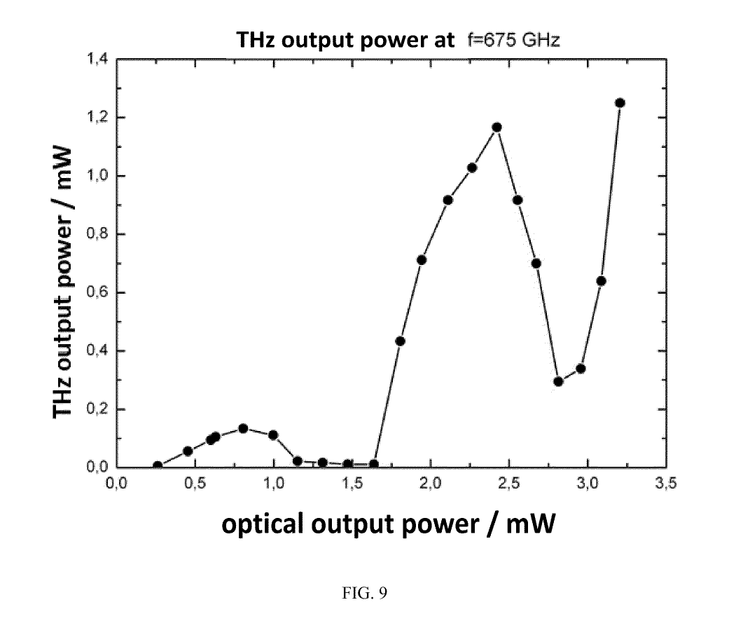

After a design improvement of the THz optics, in which the spherical lens directly in front of the TPPLN was replaced by a cylinder lens, a larger part of the emitted THz power is suitable for being captured and focused on the detector, in this case a Golay cell. This leads to a much larger THz signal of about 1.3 mW, as depicted in FIG. 9. Here, it has to be observed that only the radiation which is emitted from one of both of the sides of the TPPLN is captured.

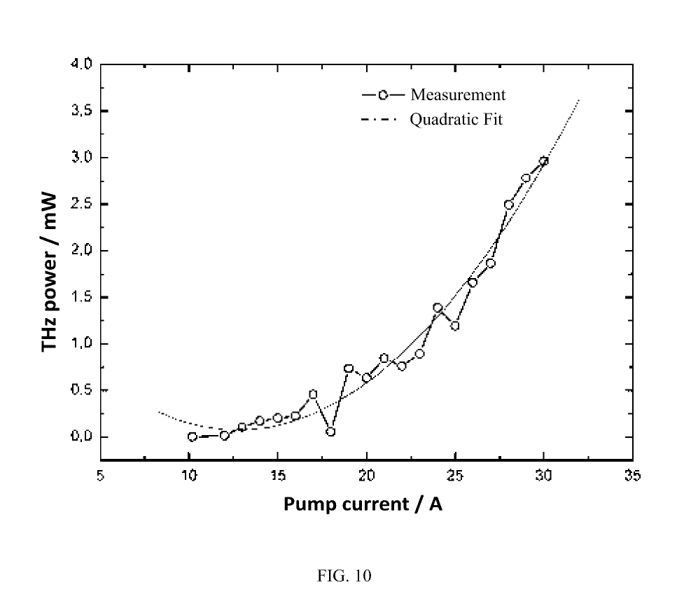

After a further design improvement, in which the resonator configuration was optimized in this case, the THz output power was able to be improved from 1.3 mW to 3 mW, as the measurement in FIG. 10 shows. This was achieved through a further concave, highly reflective mirror outside of the actual resonator. Hereby, the mirror was placed in such a way that it reflects the laser light coupled out of the cavity exactly back onto the laser chip at the folding point of the resonator. In this arrangement, the previously external concave mirror almost becomes a part of the resonator. With this measure, which only represents an intermediary stage towards a more efficient resonator configuration, it was able to be shown that the optical laser power in the resonator is able to be increased considerably, which is expressed in a significant increase of the THz signal.

Despite the impressive results already achieved, it should be noted again here that the experimental realization presented only has exemplary character. Until now, neither definitively optimized VECSEL geometries, laser materials, nonlinear crystals, nor extraction configurations have been used. The further improvements and expansions of our laser-based source for THz and millimeter waves according to the present invention are discussed in the following section.

### Embodiment Types

A central idea in one of the aspects of the present invention is generating terahertz radiation through difference-frequency generation by means of a non-linear medium positioned within the laser resonator of a laser. This terahertz radiation is then suitable for being extracted and led over a suitable THz optics.

In the following, embodiment types of laser media, resonator configurations, nonlinear media and THz optics are presented separately, respectively. The invention results from any combination of the represented embodiment.

### Laser Media

### Semiconductor Materials

Preferably, semiconductor-based laser media, i.e. lasers as known by the English term “Vertical External Cavity Surface Emitting Laser (VECSEL)” or the German term “Halbleiter Scheibenlaser” (semiconductor disc laser), are used in carrying out, according to the present invention, the patent. The spectral position of the gain region is suitable for being adjusted through the material system used and structural parameters of the individual semiconductor layer (material composition and measurement). Since no principal limitation, in reference to the laser wavelengths, exists for generating THz, it is possible, in particular, to design the active structure in such a way that a pump laser, which is as reasonably priced and/or powerful as possible, is suitable for being used.

Principally, the laser wavelengths are suitable for being chosen freely in a large range. The spectral range extends from the visible frequencies up to 6 micrometers. FIG. 11A shows, as an example, which material systems are suitable for being called on for laser wave lengths between 700 nm and 2.5 μm. This plot, however, only has exemplary character. It is in no way definitive, i.e. a certain laser wavelength is also suitable for being realized through use of another material system not shown here.

In this, attention must be paid, as a rule, that the different semiconductor materials within the VECSEL structure are able to be deposited on one another either unstrained or with only targeted straining applied. A prerequisite is a similar lattice constant. Only in this way is such a high structural performance of the laser structure ensured. FIG. 11B shows, as an example, the lattice constants and band gap energies of several semiconductors for the visible to infrared wavelength region.

With the demonstrator described above, a VECSEL design was chosen which is identical with the “Dual Wavelength VECSEL” described on pages 3-5 of U.S. 61/067,949, with the difference, however, that another nonlinear crystal was mounted tightly in front of the planar, highly reflective mirror in the demonstrator presented here.

### Laser Crystals

So-called disc lasers are also suitable for being used in devices of the present invention. In this class of laser, doped crystals are applied as the active material. Currently, Yb:YAG (ytterbium-doped yttrium aluminum garnet), which emits at a laser wavelength of 1030 nm, is primarily used as the laser material for disc lasers. There are, however, also a multitude of other materials which have already been applied or are suitable for being applied in the future. Examples are Nd or Yb doped YAG, YVO4 or LaSc₃(BO₃)₄ (LSB), Yb:KYW, Yb:KGW, Yb:KLuW and Yb:CaGdAlO4 (Yb:CALGO), Yb:Y₃Sc₂Al₃O₁₂, Yb³⁺:Y₃Al₅O₁₂, Cr⁴⁺:Y₃SCₓAl₅₋ₓO₁₂. The laser wavelength as well as the optimal pump wavelength change with the material used. Disc lasers emit outputs in the kilowatt range, so that very high THz powers are suitable for being achieved as long as the nonlinear crystal is not damaged.

### Doped Glasses

Doped glasses, as they have long been known for the production of fiber lasers, are also suitable for being used as the laser medium. For that purpose, a multitude of dopants from the class of noble earths (scandium, yttrium, lanthanum, cerium, praseodymium, neodymium, promethium, samarium, europium, gadolinium, terbium, dysprosium, holmium, erbium, thulium, ytterbium and lutetium) and different glass types (quartz glass, fluoride glass, ZBLAN, INDAT, . . . ) are available.

### Resonator Configurations

The resonator is the central element of a laser and has a decisive influence on the output capability of the entire system. An almost unmanageable multitude of resonator configurations are known from the literature, since a certain resonator configuration proves optimal for each application purpose. In the following, an overview of the possible resonator types, which are also suitable for finding application in the device according to the present invention, is given.

Generally, stable, limitedly stable and unstable resonators are suitable for being applied according to the present invention.

### Stable Resonator

Resonators are designated as stable when a paraxial light beam is reflected back and forth any number of times between the mirrors in the resonator and does not leave the resonator any more, provided diffraction losses are disregarded. There are, however, limits, in which the geometric measurements of a resonator configuration are only allowed to be located so that the resonator is still stable. A resonator is very sensitive to mechanical alterations (vibrations) and misadjustments at the stability limits, i.e., in this range, a resonator is able to switch easily from the stable to the unstable region, which in many lasers leads to an interruption of the laser activity. Examples of stable resonators are, e.g., semi-confocal and concave-convex, at the stability limits, such as e.g. plane-parallel, concentric (spherical), confocal and hemispherical configurations.

### Limitedly Stable Resonator

In this configuration, a blend is brought into the stable resonator, preferably near one or several mirrors, in order to cause a mode selection. In this way, e.g., it is able to be achieved that only the base mode expands in the resonator, however, all higher longitudinal and transversal modes experience losses and do not start to oscillate.

### Unstable Resonator

These resonator types are constructed in such a way that a paraxial laser beam leaves them after a certain number of resonator cycles. This configuration is used in laser systems which comprise high power or amplification, since here, in the case of a stable resonator, the power density on the mirrors is able to exceed the damage threshold.

### Embodiments of Resonators

In the simplest case, a linear resonator is able to consist of two mirrors, between which the light wave oscillates back and forth and a standing wave is formed. It is just as possible to place any amount of mirrors between these two end mirrors and, thus, to redirect the light wave in any desired direction. Known resonator configurations are V or W-shaped. There are also other “folds” possible.

A special form of a linear laser cavity is the multipass resonator, in which the active medium is passed through at different places. This is realized in that the laser beam is not reflected back in itself at the end mirrors, but rather displaced slightly, and only after a certain number of cycles does it reach its starting point.

A further realization form of resonators is the ring resonator. In this, no standing wave is generated through interaction of the light wave moving back and forth, but rather the cycle direction is determined through the application of an optical isolator within the resonator or a highly reflective mirror outside of the resonator. It is, however, just as possible to forgo both of these elements and to allow for two waves cycling in opposite directions in the resonator.

Elements, which are suitable for being applied within a laser resonator, are not only limited by the active laser material, but it is also possible to introduce a multitude of the most different components. In this way, e.g. lenses, etalons, Brewster windows, polarizing elements, to which the aforementioned optical isolator belongs, along with λ/2- or λ/4 slabs, polarizing beam parts, etc. are able to be used. Further possible elements are Pockels cells and saturable absorbers, which are applied for the generation of a pulse operation. Further materials are also able to comprise birefringent or nonlinear characteristics, like some crystals. It is also possible to apply light-conductive fibers in a resonator, as is used in a fiber laser, amongst others.

As a further point, several alternative resonator configurations, which partially differ from the usual resonator types and are applied in special areas, should be mentioned here. This includes resonators, which do not contain the typical plane, convex or concave mirror as a reflecting element, but rather gradient mirrors, cylinder or torus mirrors and prisms. Combinations of torus and cylinder mirrors also exist, so-called hybrid resonators, which comprise different stability values in two spatial directions standing perpendicular to one another. Likewise, a relatively new optical element, the GRISM, is suitable for being applied. This is primarily used for laser pulse compression and is a combination of a prism and an optical grating.

In choosing the mirror for the resonator, the mirrors are able to comprise either a broadband frequency behavior or an extremely narrow one, so that they, for example, reflect only the laser wavelength and feature a considerably reduced reflection capacity for all other wavelengths. Furthermore, dichromatic mirrors exist which comprise a highly reflective capacity for two wavelengths which differ from one another. Each of these mirror types is suitable for being used alone or also combined in a laser resonator.

In the following table, the examples listed above in the text are summarized again.

Resonator types:

Stable:
semi-confocal
concave-convex
At the stability limit:
plane-parallel
concentric (spherical)
confocal
hemispherical
Limitedly (one and two-sided) stable (e.g. with apertures)
each stable resonator configuration
Unstable:
countless embodiments
Folded:
V-shaped
W-shaped
further forms
Elements in the resonator:
lenses
spherical and aspherical mirrors
etalon, Brewster window
polarizing elements (opt. isolator, λ/2- or λ/4 slabs,
polarizing beam separator)
Pockels cell
birefringent or nonlinear element
light-conductive fiber
diffraction grating
prisms
GRISMs
Alternative resonator configurations
prism resonators
with gradient mirrors
Fourier transform resonator
hybrid resonators of torus or cylinder mirrors (different g-parameters
in two spatial directions standing perpendicular to one another)
for tube shaped media (with torus mirrors)
multipass
ring
dichromatic mirror
from light-conductive fiber
waveguide

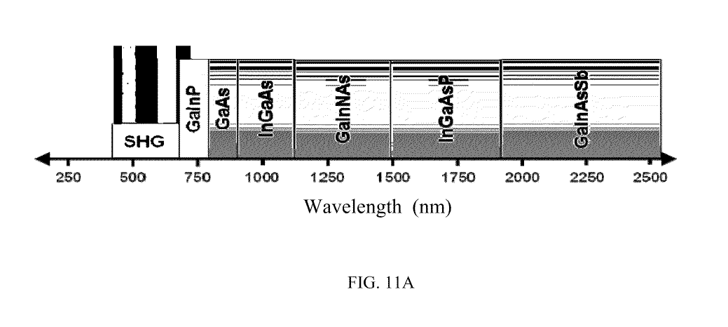

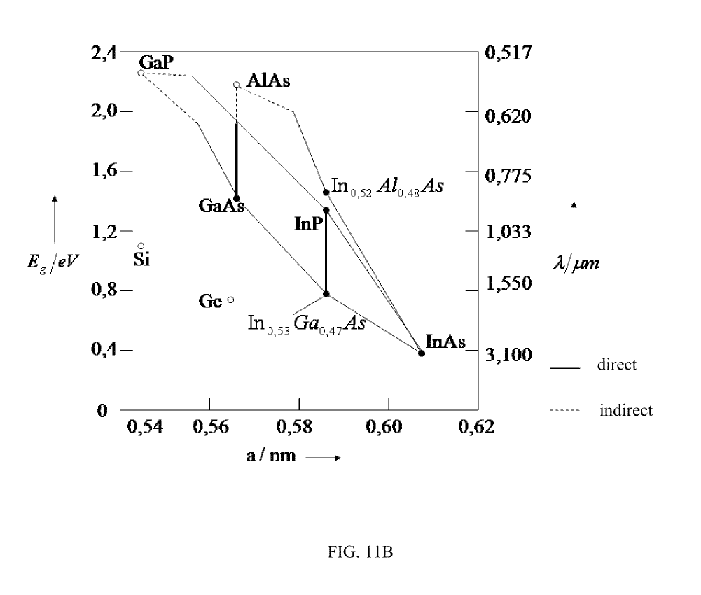

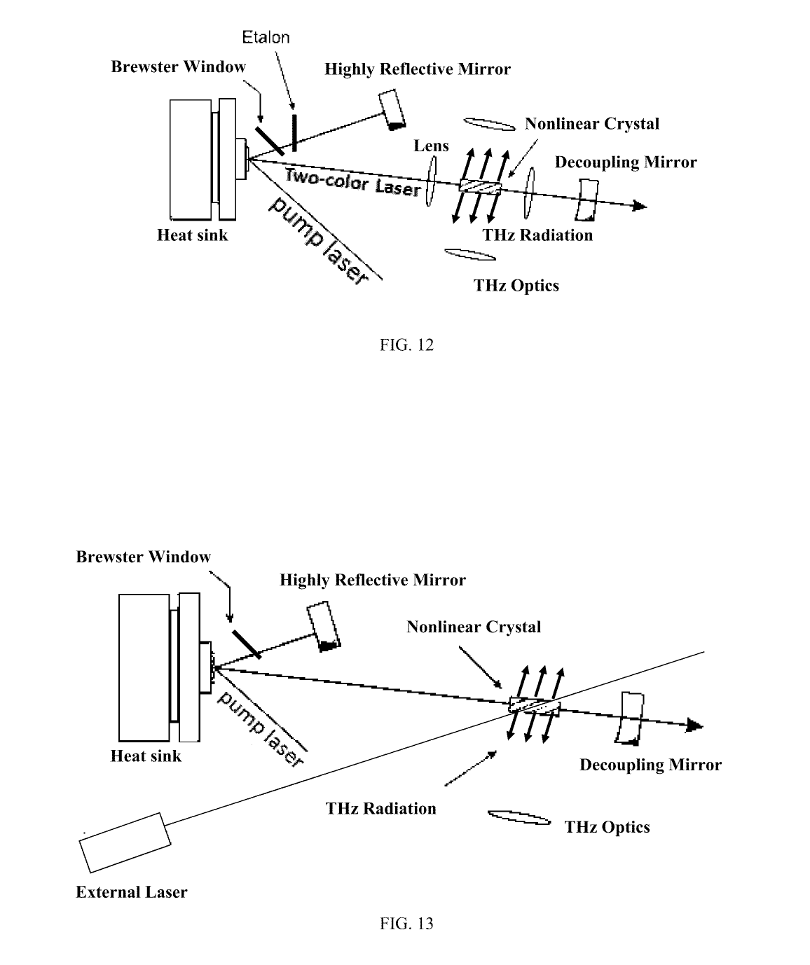

In FIGS. 12-16, several embodiments of laser resonators are depicted, which may be used with the devices of the present invention due to their good suitability. However, all of the resonator types and embodiments described above, as well as combinations thereof, are also possible. This also includes the use of the listed elements, which are suitable for being introduced in the resonator.

For example, FIG. 12 shows another possible embodiment of a resonator to extract THz signals from the 2-color VECSEL. Here two lenses are placed in the cavity to image the internal IR wave on the nonlinear crystal. The THz signal emitted normal to the crystal surface is captured and imaged by two THz lenses.

FIG. 13 shows another exemplary embodiment of a THz generation and extraction resonator geometry where the VECSEL cavity provides a single IR wavelength beam and the second IR wavelength is generated by an external laser source imaged on the nonlinear crystal.

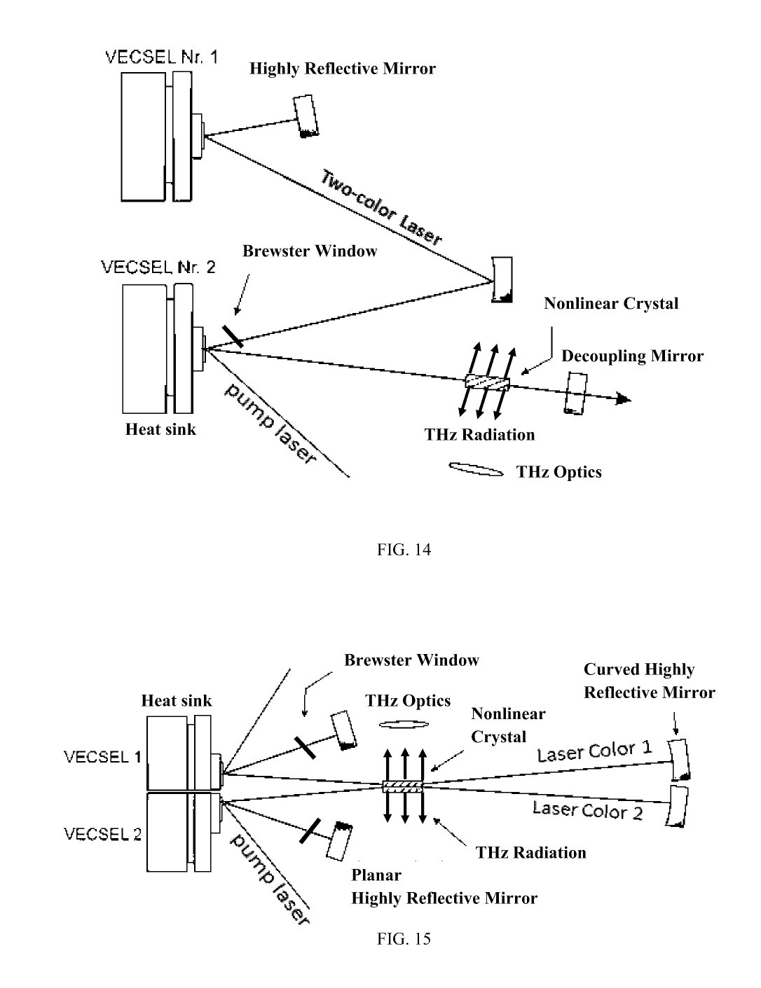

FIG. 14 shows a further exemplary embodiment of a THz generation and extraction resonator geometry where two VECSEL chips are combined in the resonator. This scheme offers many advantages. It provides additional intracavity IR power by cascading two dual-wavelength VECSEL chips in the cavity and/or the geometry allows for individual control on each VECSEL chip through temperature tuning of the wavelength. Additionally, individual VECSELs can be designed to have their peak gain at different wavelengths.

FIG. 15 shows still another exemplary embodiment of a THz generation and extraction system where again, two VECSEL chips are used but these now act as separate resonators with each generating its own IR wavelength. Both wavelengths are mixed in the common nonlinear crystal to generate the emission of THz waves.

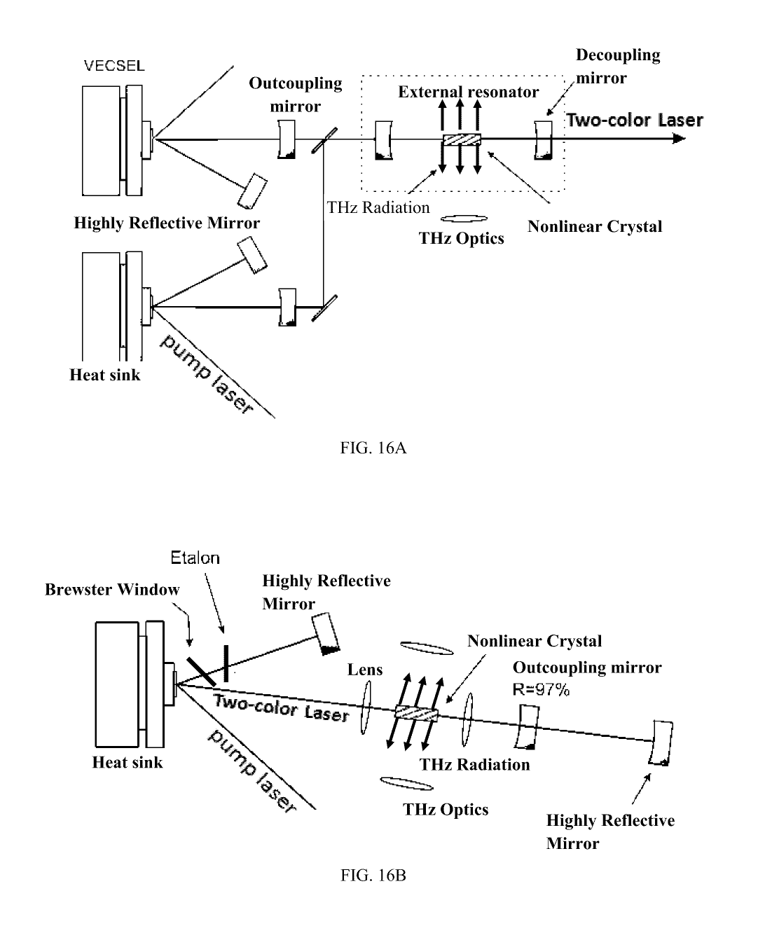

FIG. 16A shows an exemplary embodiment of another dual VECSEL cavity for the generation and extraction of THz waves. Here both VECSELs are combined in a common resonator with separate pump laser and cooling control enabling dual wavelength generation (individual wavelength from each chip). The outcoupled dual wavelength IR light is combined into a single beam and coupled into a separate resonator where one (or more) nonlinear crystals for generating the THz signal is (are) placed.

FIG. 16B shows still another exemplary embodiment of a THz generation and extraction resonator where the dual wavelength IR light that is outcoupled through the 97% partial reflecting (3% transmission) mirror is fed back into the resonator by an external high reflectivity (100%) mirror.

### THz Optics

The requirement for the THz optics is divided into three parts: initially, the THz radiation has to be efficiently outcoupled of the resonator, by separating it from the IR wave. Then, the radiation is to be extracted from the crystal in such a way that a minimum of reflection losses occurs. Subsequently, the THz waves are to be formed by means of lens optics in such a way that a collimated beam results.

### Outcoupling of the Resonator

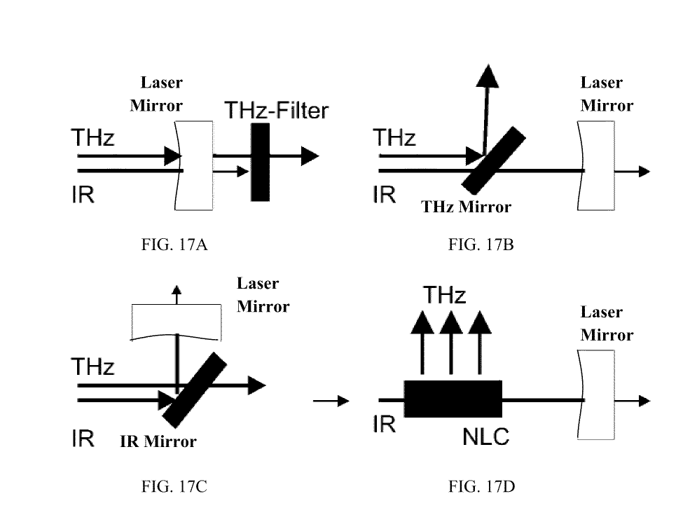

If the THz radiation is generated collinear to the resonator mode, it is able to be separated, according to the present invention, from the optical wave either within the resonator via a THz mirror, or the separation can occur behind the laser mirror, as depicted in FIG. 17A. For this purpose, the following possibilities are provided:

Behind the mirror, a filter which is transparent for THz radiation and absorbs or reflects the optical wave, is suitable for being used for separating both of the waves, FIG. 17A. This can be, for example, a polymer, a coated glass, or a semiconductor. Alternatively, a type of optical lattice is suitable for being used, which reflects the THz wave in another direction than the optical wave.

In order to separate the radiation within the cavity, a THz reflector, which is transparent for the optical wave, is suitable for being used. Here, for example, a glass coated with indium tin oxide (ITO) or with a dielectric THz mirror is provided. Alternatively, a material is suitable for being used, which comprises a high refraction index in the THz range and, thus, a high reflectivity, which is, however, only slightly reflective for the optical wave. This reflector is suitable for serving either only for the purpose of THz outcoupling or also for functioning as an etalon, in order to cause the spectral filtering of the laser lines.

Alternatively, a mirror which is highly reflective for the optical wave and slightly reflective and transparent in the THz range, is suitable for being applied within the cavity, FIGS. 17B, 17C.

If a crystal is chosen in which the THz generation occurs in such a way that the radiation is emitted from the crystal surface, the waves are automatically separated from one another, and no further separation measures are necessary. This is illustrated in FIG. 17D. This is a particularly preferable embodiment according to the present invention.

### THz Extraction Optics

Since many nonlinear crystals comprise a high refraction index, large reflection losses occur at the barrier layer between crystal and air, which reduce the useful output power of the system. In order to minimize these losses, THz anti-reflective (AR) coatings are applied, according to the present invention to the crystal. This coating can comprise, for example, a polymer film or an oxide film, which features the usual thickness for AR coatings of one-quarter wavelength. Likewise, structuring of the crystal is possible: If holes, which are much smaller than the wavelength of the THz radiation, are introduced in the crystal in the region near the surface, then an effective refraction index is formed in this region. If this coating is adjusted respective to the wavelength, reflection minimization can hereby be achieved.

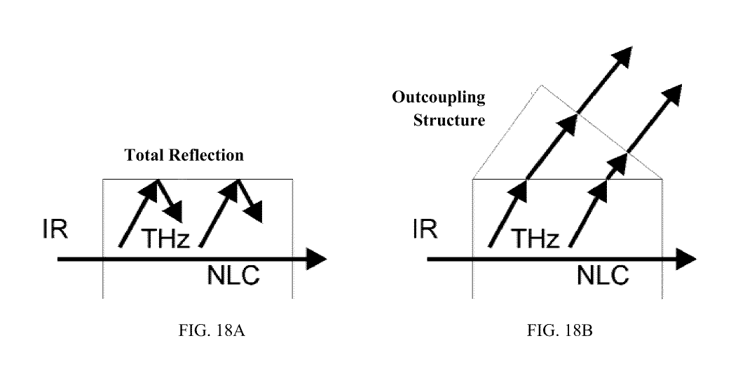

Furthermore, a large refractive index difference between crystal and air leads to an angle of the total reflection, i.e. the THz radiation, which exceeds a certain angle of incidence, is completely reflected at the boundary layer and, thus, becomes lost, FIG. 18A. In order to be able to use wave parts radiating obliquely onto the surface, a decoupling structure according to the present invention is suitable for being used. This is depicted as an example in FIG. 18B.

This decoupling structure according to the present invention can comprise, for example, an obliquely cut crystal edge, a superimposed, obliquely cut coating, a superimposed prism or a prism-like surface structuring of the crystal.

### THz Lenses

Since the source of the THz radiation is a small generating area, the emitting wave comprises a large divergence. In order to be able to use the generated radiation in the most effective way possible, a collimation of the wave by means of THz lenses is necessary.

Here, a lens design optimized on the wave form is to be chosen. If the THz wave is generated collinear, then this normally comprises a circular beam profile, so that spherical or aspherical lenses are suitable for beam shaping.

If, however, a surface-emitting crystal is used, then the line-shaped generating area causes an elliptical beam profile: A large divergence occurs in one direction; in the other direction, the beam is already nearly collimated. In this case, a THz lens is to be used, which breaks with the circle symmetry. For example, a cylinder lens is suitable for being used as the first lens object.

Generally, it is possible to carry out a precollimation by means of a lens structure which is mounted directly on the crystal. This is also suitable for being combined with the AR coating. The precollimated wave is then suitable for being completely collimated through further lenses.

In order to image the wave onto a detector, THz lenses are again suitable for being used.

In each case, the following lenses represent possible components for the system: spherical lenses, aspherical lenses, cylinder lenses, aspherical cylinder lenses, Fresnel lenses and GRIN lenses.

### Crystals

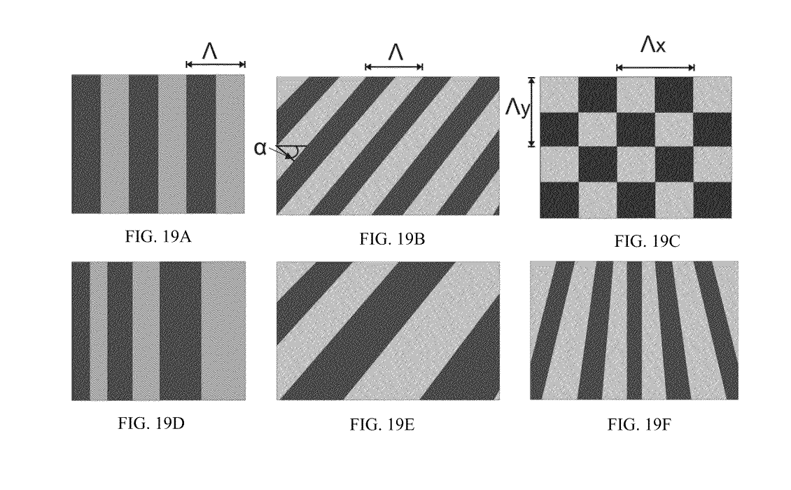

For efficient conversion, phase matching between the generated THz wave and the optical wave is to be achieved. In this, phase matching can be obtained either for a collinear wave expansion or for a noncollinear wave expansion. This can be achieved in different ways according to the present invention:
Via quasi phase matching: The ferroelectric crystal domains are poled one-, two- or multi-dimensionally. The polarity is to be matched periodically, aperiodically or in another way to the frequencies and emission direction used. In particular, a tilted/untilted periodic polarity, a tilted/untilted aperiodic polarity, a chessboard-shaped polarity, a fan-out polarity and a combination of these are suitable for being used. Examples are outlined in FIG. 19a-19F (For clarification, the polarity period Λ 19A-B, the tilting angle of the polarity α 19B, and the two-dimensional polarities Λₓ and Λ_{y} 19C are depicted.).
Via birefringence: Many nonlinear crystals feature birefringent characteristics, i.e. the refraction index depends on the polarization direction of the electromagnetic wave relative to the crystal axes. Hereby, ordinary and extraordinary beams are differentiated. If a birefringent crystal is cut at a certain angle, then the effective refraction index of the extraordinary beam is able to change as a function of the cutting angle. Phase matching is to be achieved through this principle.
Nonlinear materials are suitable for being chosen, which fulfill phase matching without further modification.
Via waveguide structures: The nonlinear medium can be carried out in the form of a waveguide. Through this waveguide, guidance of the optical waves and/or the THz wave is able to occur. If all waves are guided, the design is to be realized in such a way that the effective group velocities of all waves are matched, i.e. the effective refraction indices vary from one another as little as possible. In order to realize this, all waveguide configurations described in textbooks are available (see e.g. Karl J. Ebeling, Integrierte Optoelektronik, Springer, Berlin, 1992.). Examples of this are raised strip waveguides, flushly embedded strip waveguides, buried strip waveguides, ridge waveguides, inverted ridge waveguides, dielectric slab waveguides, metal slab waveguides. However, countless further possibilities still result, since the nonlinear material (or the nonlinear materials) is (are) suitable for being combined with other materials as well, which comprise a very small or negligible nonlinear coefficient, but a refraction index suitable for achieving phase matching, for the realization of a waveguide. Generally, in order to achieve phase matching through wave guidance, a structured or unstructured nonlinear crystal or a combination of one or several structured or unstructured nonlinear media and other structured or unstructured materials is suitable for being used.
Additionally, waveguides and/or nonlinear materials, which comprise photonic crystal structures or depend on so-called metamaterials with a negative refraction index, are also possible.

All substances which comprise a nonlinear coefficient are suitable as materials. For optimal conversion efficiency, the material should possess a maximal nonlinear coefficient and a minimal absorption in the THz range. There are also materials suitable which allow nonlinear mixtures of a higher order, for example four-wave mixture or five-wave mixture.

In particular, the following materials are available as a nonlinear medium. Hereby, these are suitable for being used either in pure form or doped. These are also, optionally, to be provided with a QPM, to be cut at a certain angle or to be structured as a waveguide:
Lithium niobate (LiNbO₃) in congruent and stoichiometric form. This material is suitable for being provided with a QPM particularly efficiently. In particular, periodically poled lithium niobate (PPLN), tilted periodically poled lithium niobate (TPPLN), aperiodically poled lithium niobate (APPLN), tilted aperiodically poled lithium niobate (TAPPLN), chessboard-shaped poled lithium niobate and lithium niobate with a fan-out polarity are suitable.
Another embodiment is an unstructured lithium niobate crystal, which is provided with an outcoupling structure, in order to use THz irradiation under the Cherenkov angle.
In order to reduce the photorefractive effect, these embodiments are suitable for being doped with other substances, for example with magnesium oxide (MgO) or manganese (Mn).
GaAs.
Zinc germanium diphosphide (ZGP, ZnGeP₂), silver gallium sulfide and selenide (AgGaS₂ and AgGaSe₂), and cadmium selenide (CdSe)
ZnSe
GaP
GaSe
Lithium tantalate (LiTaO₃)
Lithium triborate
Potassium niobate (KNbO₃)
Potassium titanyl phosphates (KTP, KTiOPO₄)
All materials from the “KTP family” and also KTA (KTiOAsO₄), RTP(RbTiOPO₄) and RTA (RbTiAsPO₄), are likewise suitable for being periodically poled
Potassium dihydrogen phosphate (KDP, KH2PO4) and potassium dideuterium phosphate (KD*P, KD₂PO₄)
Beta barium borate (beta-BaB₂O₄=BBO, BiB₃O₆=BIBO), and cesium borate (CSB₃O₅=CBO), lithium triborate (LiB₃O₅=LBO), cesium lithium borate (CLBO, CsLiB₆O₁₀), strontium beryllium borate (Sr₂Be₂B₂O₇═SBBO), yttrium calcium oxyborate (YCOB) and K₂Al₂B₂O₇=KAB
Organic nonlinear media, in particular DAST.
Nonlinear media on a polymer basis, for example electro-optical polymers, in particular, all compounds which comprise amorphic polycarbonates or phenyltetraenes.
Silicon or strained silicon
Furthermore, all semiconductor materials, in strained or unstrained form, which comprise a non-disappearing, nonlinear χ-coefficient.

The crystals can be designed in such a way that the THz irradiation occurs collinear or noncollinear to the optical waves. Hereby, the crystals can be provided with THz-anti-reflective and/or outcoupling structures in order to better extract the generated waves from them.

The current demonstrator has been examined in CW operation, since the VECSEL is continuously pumped and neither an active nor a passive element is located within the resonator which would enable a pulsed emission

In a further embodiment, the simplest possibility for operating the device in a pulsed manner consists in pulsing the pump laser, in order to finally obtain a higher intracavity power.

Further possibilities for running the VECSEL in pulse operation, especially regarding the generation of considerably shorter pulses and, thus, significantly higher intensities, comprises the application of active or passive elements, which are hereinafter described:

An active element can be incorporated in the resonator, e.g. a Q switching, in order generate pulses in the range of nanoseconds or picoseconds.

In order to achieve even shorter pulses in the range of femtoseconds, e.g. a saturable absorber can be integrated into the resonator as a passive element. These ultrashort pulses are achieved by means of the so called mode coupling.

Several publications and patent documents are cited in this application in order to more fully describe the state of the art to which this invention pertains. The disclosure of each of these citations is incorporated by reference herein.

These and other advantages of the present invention will be apparent to those skilled in the art from the foregoing specification. Accordingly, it will be recognized by those skilled in the art that changes or modifications may be made to the above-described embodiments without departing from the broad inventive concepts of the invention. It should therefore be understood that this invention is not limited to the particular embodiments described herein, but is intended to include all changes and modifications that are within the scope and spirit of the invention as set forth in the claims.

What is claimed is:

1. Generation of electromagnetic radiation in the terahertz and millimeter range characterized by the following principal processing steps:
a) Provision of a nonlinear medium;
b) Positioning of this medium within a laser resonator of a Vertical External Cavity Surface Emitting Laser (VECSEL) or another laser, wherein the other laser is preferably a disc laser;
c) Two-color or multi-color operation of the laser in such a way that terahertz (THz) radiation is generated through difference-frequency generation inside the cavity.

2. Method to extract the THz radiation generated according to claim 1 by means of a method, wherein a suitable THz optic is used which has been optimized for that purpose, wherein this optics is characterized by the fact that
a) it suitably separates the THz radiation from the optical waves, wherein suitable separation
I. takes place inside of or outside the resonator
II. is able to take place by means of a filter element which absorbs the THz radiation and the optical radiation at different strengths and/or reflects at different strengths and/or reflects at different angles and/or bends at different angles, the filter element particularly able
i. to be realized through a suitable substrate which is transparent for the optical wave and is suitably coated with indium tin oxide (ITO) or with a dielectric THz mirror or with another suitable optically transparent material, where this element reflects the THz radiation and lets the optical wave pass,
ii. or to be realized through a material which comprises a high refraction index in the THz range and, thus, a high reflectivity, but is only slightly reflective for the optical wave,
iii. or to be realized through a suitable substrate which is transparent for the THz wave and is suitably coated with a dielectric mirror for the optical wave or with another suitable material which is transparent in the THz range, where this element reflects the optical radiation and lets the THz wave pass,
iv. or to be realized through a material which comprises a high reflectivity in the optical range, but is only slightly reflective for the THz wave,
v. or to be realized through an optical lattice, which bends the THz radiation in another direction than the optical radiation,
vi. or to be realized through a polymer or coated glass or semiconductor material which is transparent for the THz radiation and absorbs the optical wave,
vii. to be used within the cavity as etalon, if suitable,
viii. to be coated with an anti-reflective coating for the optical wavelengths, if suitable,
ix. to be coated with an anti-reflective coating for the THz wavelengths, if suitable,
III. or is able to take place by means of a crystal, which does not emit the THz radiation collinearly to the optical wave;
IV. or is able to take place by means of the laser mirrors, which are transparent for the THz waves, but opaque for the optical wave;
b) it suitably minimizes the reflection losses of the THz radiation, i.e. in particular through
I. a suitable THz-anti-reflective coating of the optical components or/and
II. use of the Brewster angle or/and
III. use of suitable, slightly reflective materials or/and
IV. outcoupling structures which suitably adjusts the THz radiation generated within the crystal to the environment in order to avoid total reflection
c) it collects suitably the THz radiation and shapes it, i.e. is arranged by beam-shaping elements, wherein these elements
I. suitably comprise formed THz lenses and/or THz mirrors, in particular made of spherical lenses or/and aspherical lenses or/and cylinder lenses or/and aspherical cylinder lenses or/and Fresnel lenses or/and GRIN lenses or/and parabolic mirrors or/and spherical mirrors and/or elliptical mirrors
II. collect and image as much as possible of the generated radiation
III. minimize the imaging error
IV. cause as little loss as possible through absorption and/or reflection and/or scattering.

3. Method according to claims 1 to 2, wherein materials are used which comprise a suitable gain spectrum, wherein, depending on the planned application, a suitable gain spectrum
a) provides as high an amplification as possible for a given charge carriers' density (for high THz output power)
b) comprises as large of spectral bandwidth as possible (for tunability of the generated THz radiation)
c) comprises an optimized spectral position in relation to available pump lasers (use of cheap and/or powerful commercial pump sources).

4. Method according to claims 1 to 3, wherein the power density available within the nonlinear crystal is maximized by
a) placing the crystal where the laser beam has its smallest diameter within the resonator (in the actual demonstrator: directly in front of the planar, highly reflective mirror);
b) positioning one further concave, highly reflective mirror outside the resonator in the laser beam and reflecting the beam exactly to the active medium, where the additional mirror is coupled with the resonator and the optical intensity within the resonator is considerably increased;
c) replacing the partly transparent output coupler by a highly reflective mirror with shorter, identical or longer focal length, where the power density within the resonator is able to be significantly increased;
d) bundling the laser irradiation within the resonator in the area of the crystal by means of lenses; and
e) running two separate VECSEL in a joint resonator, wherein one of both or both are suitable for being modified in their laser wavelength and, thus, for generating a significantly higher intracavitary intensity than one individual VECSEL.

5. Method according to claims 1 to 4, wherein
a) as high a conversion efficiency as possible is achieved
b) the phase matching is achieved in a suitable manner, i.e. phase matching is characterized in the fact that
I. it is fulfilled for an embodiment of a THz source which is tunable over a wide spectral range
II. or it is optimized for an embodiment of a THz source with a fixed frequency
III. or it is able to be achieved through the use of suitable nonlinear crystals, which is caused due to their material parameter
IV. or it is able to be achieved in particular through the use of suitable birefringent nonlinear crystals
V. or it is able to be achieved, in particular, through a suitable quasi-phase-matching (QPM) (through the polarity of the ferroelectric domains in the crystal). This polarity is able to comprise, in particular, a tilted/untilted periodic polarity, a tilted/untilted aperiodic polarity, a chessboard-shaped polarity, a fan-out polarity or a combination thereof.
VI. or it is able to be achieved, in particular, through a suitable waveguide structure with nonlinear elements. Within this waveguide structure, a guidance of the waves is able to take place. This guidance is characterized by the fact that
i. either only the optical waves or only the THz waves or both of them are able to be guided
ii. the effective group velocities or the effective refraction indices of the waves are adjusted
iii. an as big as possible overlapping is achieved between the optical wave and nonlinear material
iv. an as small as possible mode radius of the optical wave within the nonlinear material is obtained
v. it is able to be achieved, in particular, with a structured or unstructured nonlinear crystal or a combination of one or several structured or unstructured nonlinear media and other structured or unstructured materials
vi. it is able to be achieved, in particular, through strip waveguides, flushly embedded strip waveguides, buried strip waveguides, ridge waveguides, inverted ridge waveguides, dielectric slab waveguides, metal slab waveguides
vii. it is able to be achieved, in particular, through photonic crystal structures
c) the THz radiation is emitted in a suitable direction, i.e. collinear or under a suitable angle, wherein this is able to be adjusted, for example, through the selection of the crystal material or the QPM
d) the absorption losses are minimized
e) the reflection losses are minimized
f) the impact on the resonator mode is optimized (small perturbation of the mode in order not to negatively influence the efficiency and beam form or targeted influence in order to use the crystal as a part of the resonator)
g) suitable materials are used, i.e. wherein said materials
I. comprise a nonlinear coefficient of second or higher order
II. comprise as high a nonlinear coefficient as possible
III. comprise as little an absorption coefficient as possible
IV. comprise as high a damage threshold as possible
V. are suitable for being doped in order to increase the damage threshold and/or the nonlinear coefficient and/or to decrease the absorption
VI. are suitable for comprising the following substances:
Lithium niobate (LiNbO₃) in congruent and stoichiometric form. This material is suitable for being provided with a QPM particularly efficiently. In particular, periodically poled lithium niobate (PPLN), tilted periodically poled lithium niobate (TPPLN), aperiodically poled lithium niobate (APPLN), tilted aperiodically poled lithium niobate (TAPPLN), chessboard-shaped poled lithium niobate and lithium niobate with a fan-out polarity are suitable. Another embodiment is an unstructured bulk lithium niobate crystal, which is provided with an outcoupling structure, in order to use THz irradiation under the Cherenkov angle. In order to reduce the photorefractive effect, these embodiments are suitable for being doped with other substances, for example with magnesium oxide (MgO) or manganese (Mn)
or GaAs
or zinc germanium diphosphide (ZGP, ZnGeP₂), silver gallium sulfide and selenide (AgGaS₂ and AgGaSe₂), and cadmium selenide (CdSe)
or ZnSe
or GaP
or GaSe
or lithium tantalate (LiTaO₃)
or Lithium triborate
or potassium niobate (KNbO₃)
or potassium titanyl phosphates (KTP, KTiOPO₄)
or all materials from the “KTP family” and also KTA (KTiOAsO₄), RTP(RbTiOPO₄) and RTA (RbTiAsPO₄), are likewise suitable for being periodically poled
or potassium dihydrogen phosphate (KDP, KH2PO4) and potassium dideuterium phosphate (KD*P, I(D₂PO₄)
or beta barium borate (beta-BaB₂O₄=BBO, BiB₃O₆=BIBO, and cesium borate (CSB₃O₅=CBO), lithium triborate (LiB₃O₅=LBO), cesium lithium borate (CLBO, CsLiB₆O₁₀), strontium beryllium borate (Sr₂Be₂B₂O₇=SBBO), yttrium calcium oxyborate (YCOB) and K₂Al₂B₂O₇=KAB
or organic nonlinear media, in particular DAST
or nonlinear media on a polymer basis, for example electro-optical polymers, in particular, all compounds which comprise amorphic polycarbonates or phenyltetraenes
or silicon or strained silicon
or furthermore, all semiconductor materials, in strained or unstrained form, which comprise a non-disappearing, nonlinear x-coefficient.

6. Device for the generation of electromagnetic radiation in the terahertz and millimeter range, wherein the device comprises:
a) a laser resonator with laser light source integrated therein in the form of at least one VECSEL or at least one further laser light source, preferably a disc laser, wherein at least one laser light source is arranged in such a way that it is suitable for being run in two- or multi-color operation,
b) a nonlinear medium, wherein the medium is realized for the difference-frequency generation in the terahertz or millimeter range and arranged within the laser resonator,
c) means for the extraction of electromagnetic radiation in the terahertz and millimeter range out of the laser resonator, wherein these are arranged either inside or outside the resonator.

7. Device according to claim 6, wherein the nonlinear medium and the means for the extraction are arranged jointly in the form of a nonlinear crystal.

8. Device according to claim 6, wherein, if a VECSEL is used, the device comprises means for the optical or electrical pumping of the VECSEL suitably arranged for that and interacting with these means.

9. Device according to claims 6 to 8, wherein the device is realized for continuous wave (cw) or pulsed operation.

10. Device according to claims 7 to 9, wherein the nonlinear crystal comprises an outcoupling structure in order to avoid reflection losses at the boundary layer between crystal and air, wherein this outcoupling structure comprises, for example, an obliquely cut crystal edge, a superimposed, obliquely cut coating, a superimposed prism or a prism-like surface structuring of the crystal.

11. Nonlinear medium for the conversion of IR radiation into terahertz waves, wherein said medium is realized in the form of a periodically poled lithium niobate (TPPLN), which comprises a tilted structure in relation to the crystal surface and, thus, also a periodical polarity in the direction of the emitted THz waves in such a way that destructive interference of the formed THz waves is compensated and the IR beam diameter is able to be chosen significantly larger without any reduction of the conversion efficiency.
